(19) United States
(12) Patent Application Publication
(10) Pub. No.: US 2014/0085995 A1
(43) Pub. Date: Mar. 27, 2014

(54) METHOD, APPARATUS AND SYSTEM FOR DETERMINING A COUNT OF ACCESSES TO A ROW OF MEMORY

(71) Applicants: Zvika Greenfield, Kfar Sava (IL); John B. Halbert, Beaverton, OR (US); Kuljit S. Bains, Olympia, WA (US)

(72) Inventors: Zvika Greenfield, Kfar Sava (IL); John B. Halbert, Beaverton, OR (US); Kuljit S. Bains, Olympia, WA (US)

(21) Appl. No.: 13/626,479

(22) Filed: Sep. 25, 2012

(51) Int. Cl. G11C 29/00

(52) U.S. Cl. 365/201

(57) ABSTRACT

Techniques and mechanisms for determining a count of accesses to a row of a memory device. In an embodiment, the memory device includes a counter comprising circuitry to increment a value of the count in response to detecting a command to activate the row. Circuitry of counter may further set a value of the count to a baseline value in response to detecting a command to refresh the row. In another embodiment, the memory device includes evaluation logic to compare a value of the count to a threshold value. A signal is generated based on the comparison to indicate whether a row hammer event for the row is indicated.

### BACKGROUND

1. Technical Field

Embodiments of the invention are generally related to memory management, and more particularly, but not exclusively, to the control of memory refresh operations.

2. Background Art

With advances in computing technology, computing devices are smaller and have much more processing power. Additionally, they include more and more storage and memory to meet the needs of the programming and computing performed on the devices. The shrinking size of the devices together with the increased storage capacity is achieved by providing higher density devices, where the atomic storage units within a memory device have smaller and smaller geometries.

With the latest generation of increased density, intermittent failure has appeared in some devices. For example, some existing DDR3 based systems experience intermittent failures with heavy workloads. Researchers have traced the failures to repeated access to a single row of memory within the refresh window of the memory cell. For example, for a 32 nm process, if a row is accessed 550K times or more in the 64 millisecond refresh window, the physically adjacent wordline to the accessed row has a very high probability of experiencing data corruption. The row hammering or repeated access to a single row can cause migration across the passgate. The leakage and parasitic currents caused by the repeated access to one row cause data corruption in a non-accessed physically adjacent row. The failure issue has been labeled as a ‘row hammer’ or ‘1 row disturb’ issue by the DRAM industry where it is most frequently seen.

### BRIEF DESCRIPTION OF THE DRAWINGS

The various embodiments of the present invention are illustrated by way of example, and not by way of limitation, in the figures of the accompanying drawings and in which:

FIG. 1 is a block diagram illustrating element of a system for monitoring accesses to a row of memory according to an embodiment.

FIG. 2 is a block diagram illustrating element of a memory device for monitoring accesses to a row of memory according to an embodiment.

FIG. 3 is a flow diagram illustrating elements of a method for maintaining a count of row accesses according to an embodiment.

FIG. 4 is a block diagram illustrating element of a memory device for maintaining a count of row accesses according to an embodiment.

FIG. 5 is a block diagram illustrating elements of a computing system for detecting a row hammer event according to an embodiment.

FIG. 6 is a block diagram illustrating elements of a mobile device for detecting a row hammer event according to an embodiment.

### DETAILED DESCRIPTION

As described herein, certain embodiments variously provide mechanisms and/or techniques for maintaining a count of accesses to a row of a memory device. Certain features of various embodiments are discussed herein with respect to determining such a count of accesses for detection of a row hammer event. However, such discussion may be extended to additionally or alternatively apply to determining such an access count for applications other than row hammer detection.

As used herein in the context of an access to a row of a memory device, “access” refers to an event which changes an operational state of storage circuitry of the row. For example, a row access may include an operation—e.g. in the service of an Activate command or a Precharge command—changing one or more functional characteristics of a row's storage elements. Alternatively or in addition, a row access may include an operation which reads, writes, erases or otherwise touches data stored by, or to be stored by, such storage elements of a row. Certain embodiments variously distinguish between types of accesses which variously increase a risk of a row hammer event, and types of accesses which variously decrease a risk of a row hammer event. Certain embodiments maintain a count of accesses which are each of only a certain access type (or one of only certain access types).

When a specific row of a memory device is repeatedly accessed within a certain time window, a physically adjacent row may experience data corruption. The repeated access within the time window is referred to herein as a row hammer event or row hammer condition. The physically adjacent row is a victim row to the row hammer event. As described herein the memory controller may receive an indication of a row hammer event, in which a specific row is accessed more than a threshold number of times within the time window. The memory controller may identify the row associated with the row hammer event, and send one or more commands to the memory device to cause the memory device to perform a targeted refresh to reduce the likelihood of data corruption in a victim row or rows.

The theoretical maximum number of times a row can be accessed within a 64 ms window (e.g., a refresh window) is 1.35 million times (64 ms refresh window divided by 47 ns access time) for current DRAMs (dynamic random access memory). The practical maximum without risking data corruption in the victim rows is much lower, and depends on the process technology used. However, by detecting a row hammer event and sending one or more commands to implement a targeted refresh, the risk of data corruption can be reduced without restricting access to a specific row of memory. The examples provided herein primarily discuss the row hammer issue with respect to DRAM. However, it will be understood that the row hammer issue is more generally a memory device scaling issue, which occurs as memory densities increase. Thus, the descriptions with respect to DRAM will be understood as non-limiting examples that can be applied to other memory technologies.

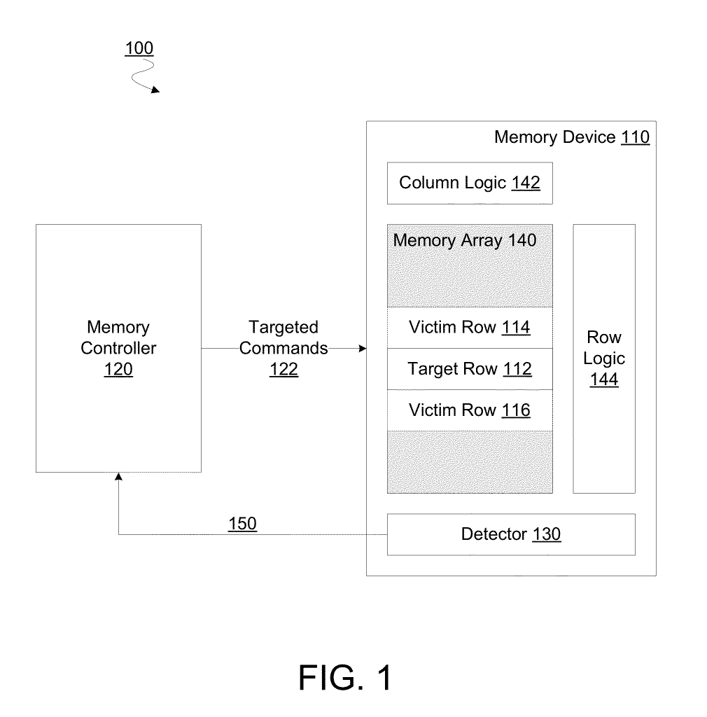

FIG. 1 is a block diagram of an embodiment of a system 100 that monitors accesses to a row of memory. System 100 may include memory device 110 coupled to memory controller 120. Memory device 110 may include any type of memory technology that has rows of memory cells, where data is accessible via a wordline or the equivalent. In one embodiment, memory device 110 includes dynamic random access memory (DRAM) technology.

Memory device 110 may include memory array 140, which represents one or more logical and/or physical groups of memory. An example of a grouping of memory is a bank of memory. Memory device 110 may include column logic 142 and row logic 144, which are used to decode an access instruction to the proper memory location within memory array 140. There is no requirement for the number of rows and columns to be equal, and in fact they are typically not equal. Memory controller 120 may send commands or instructions to memory device 110 over a command bus (e.g., a command/address (C/A) bus), which are then interpreted by memory device 110. Memory device 110 may decode the command information to perform a variety of access functions within the memory, and decode address information via column logic 142 and row logic 144. The logic may access a specific location in memory with a combination of a column address strobe or signal (CAS) and a row address strobe or signal (RAS). Rows of memory may be implemented in accordance with known memory architectures or their derivatives. Briefly, a row of memory may include one or more addressable columns of memory cells, as identified by the CAS generated by column logic 142. The rows are addressable via the RAS generated by row logic 144.

Memory array 140 may include one or more rows that are the targets of repeated access within a time window. Such a row is subject to a row hammer condition. In many modern memory devices, the architecture of the semiconductor layout causes one or more physically adjacent rows to be at risk of becoming corrupted. The row or rows at risk of becoming corrupted due to row hammer condition are referred to herein as victim rows. At a given time during operation of system 100, memory array 140 may include target row 112, which is a row of memory subject to hammering, or being accessed repeatedly within a given time period. The target row 112 is the target of the row hammer event. In many modern memory devices, the architecture of the semiconductor layout causes one or more physically adjacent rows to be at risk of becoming corrupted. The rows at risk of becoming corrupted due to row hammer of target row 112 are illustrated as victim row 114 and victim row 116. Either or both of victim rows 114, 116 may be at risk, depending on the physical layout of memory device 110.

It will be understood that different memory device manufacturers use different logic and architectures to utilize the memory resources of the devices. For example, different memory device manufacturers may use different offsets to map between logical memory addresses used in the host processor (not shown) and the physical memory addresses used internally to memory device 110. In one embodiment, memory controller 120 utilizes the same logical memory addresses as used by a host processor (not shown) of system 100. Thus, in one embodiment, memory controller 120 may provide a row address to memory device 110 indicating a particular row. The memory controller 120 may indicate the row address in conjunction with and/or as part of a command that it issues to memory device 110.

Memory device 110 may include a detector 130 comprising circuit logic that enables system 100 to maintain a count of accesses to a row of memory array 140. For brevity, a count of accesses to a given row of a memory device is referred to herein as an access count, where the access count is for that given row. The mechanisms of detector 130 may include, for example, some way of determining a number of times a row of memory 140 is accessed by commands—e.g. where each such command is of a particular command type or of any of multiple command types. By way of illustration and not limitation, detector 130 may include logic to monitor commands from memory controller 120 to identify commands—e.g. including any commands of an Activate command type, a read command type and/or a write command type—which are for accessing a particular row. In an embodiment, detector 130 may increment a current access count for that particular row in response to detecting any of one or more types of accesses that increase a risk of a row hammer condition.

A row hammer event is not simply about how many times a row is accessed, but how many times in a given time period. Once a row is refreshed, the conditions that could cause data corruption are overcome. Thus, maintaining an access count should, in an embodiment, be based at least in part on data refresh operations. Detector 130 may additionally or alternatively include, for example, a mechanism to reset an access count for a given row to a baseline value in response to some reset event. For example, detector 130 may include logic to detect for an indication of an access to a row is of a type that reduces a risk of a row hammer condition—e.g. an access to implement, at least in part, a data refresh for a particular row of memory array 140. Such a refresh event may include, for example, a targeted refresh to only that particular row, a refresh to a bank (or other group) of rows which includes that particular row, a scheduled (e.g. periodic) refresh and/or any of a variety of other types of data refreshes. In an embodiment, logic of detector 130 may detect a refresh event in response to monitoring commands from memory controller 120 to identify any of one or more types of commands—e.g. including an Activate command type and/or a Precharge command type—which are for refreshing data of a given row.

In an embodiment, detector 130 includes logic to send a signal 150 to memory controller 120 that an access count for a given row of memory 140 has exceeded a threshold level—e.g. where the signal 150 is to indicate a row hammer event. In an embodiment, memory controller 120 generates, in response to signal 150, targeted commands 122 for causing memory device 110 to variously perform targeted refreshes of respective rows. In one embodiment, targeted commands 122 includes a command or series of commands for refreshing a particular row of memory array 140. For example, in one embodiment, such a sequence may include an Activate command, followed by a Precharge command—e.g. which results in a data refresh of one or both of victim rows 114, 116. Any of a variety of additional or alternative commands for refreshing a victim row or victim rows may be included in target commands 122, according to different embodiments. Targeted commands 122 may overcome the conditions that cause data corruption in between normally scheduled refresh event that may occur periodically on a refresh cycle.

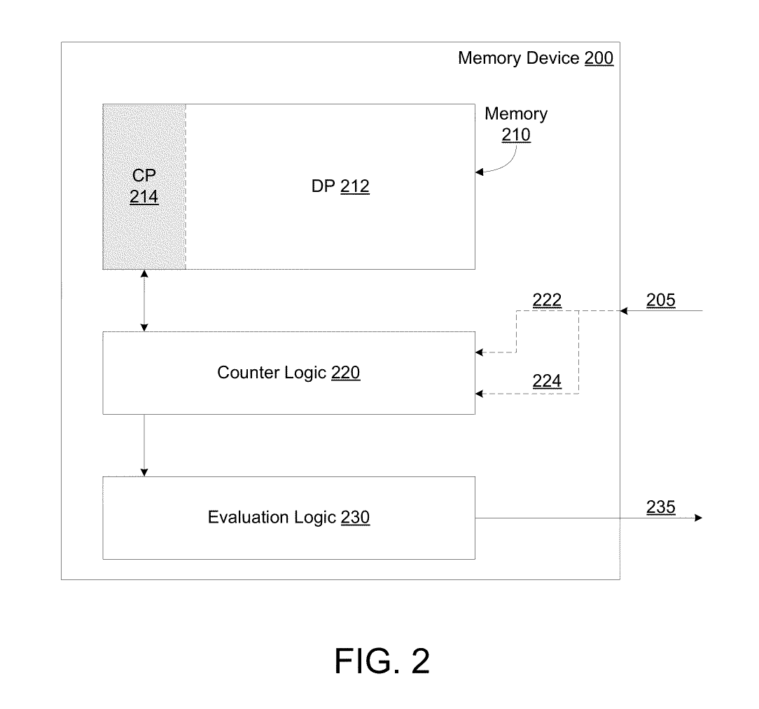

FIG. 2 illustrates elements of a memory device 200 to maintain an access count for a memory row according to an embodiment. Memory device 200 may include logic to enable a system—e.g. system 100—to detect for a row hammer event and, in an embodiment, to provide one or more data refreshes in response to such a row hammer event. In an embodiment, memory device 200 includes some or all of the features of memory device 110.

Memory device 200 may include memory 210 comprising storage cells to variously store data which, for example, is available for access by a host coupled to memory device 200 via a memory controller (not shown). In an embodiment, such storage cells are arranged in addressable rows which include some or all of the features of memory array 140. During operation of memory device 200, storage cells of memory 210 may be subject to a risk of data corruption—e.g. including data corruption due to a row hammer event. Storage cells of memory 210 may include cells which require occasional data refreshes. Such storage cells may, for example, include capacitive memory cells of a DRAM, although certain embodiments are not limited in this regard.

In an embodiment, memory 210 includes a data portion DP 212, including at least a portion of a row to store data for access with a memory controller, and a count portion CP 214 to store an access count for that row. Memory 210 may include other storage cells (not shown) in addition to those of DP212, CP 214. One or more addressable rows of memory 210 may each span DP 212 and CP 214, although certain embodiments are not limited in this regard. By way of illustration and not limitation, DP 212 may include a portion of a first row which is to variously store data, where CP 214 includes another portion of that first row which is for storing a value specifying an access count for that first row. In an embodiment, memory 210 includes multiple such rows which each have a respective portion (e.g. in DP 212) to store data and another respective portion (e.g. in CP 214) to store an access count for that row. Alternatively or in addition, DP 212 may include all of an addressable row for storing data, where CP 214 stores a value external to that addressable row, the value specifying an access count for that addressable row. In such an embodiment, memory device 200 may include logic to map the access count value stored in CP 214 with the corresponding row in DP 212.

Memory device 200 may further include counter logic 220 coupled to memory 210 (e.g. coupled to CP 214), where counter logic 220 includes hardware to maintain respective access counts for one or more rows. For example, memory device 200 may receive, from a memory controller or other such agent, commands 205 including one or more commands to variously access an addressable row of memory 210. In an embodiment, DP 212 includes at least a portion of such an addressable row. DP 212 may further include portions of one or more other addressable rows, although certain embodiments are not limited in this regard.

Memory device 200 may include memory access logic (not shown) —such as that of column logic 142 and/or that of row logic 144—to receive commands 205 and to variously operate memory cells of memory 210 for the purpose of servicing commands 205. Mechanisms of such memory access logic may, for example, be implemented with any of a variety of conventional structures which are not limiting on certain embodiments. To avoid obscuring certain features of various embodiments, such memory access mechanisms are not shown in memory device 200.

In an embodiment, counter logic 220 detects, based on one or more of commands 205, an indication 222 of an access to a row of memory 210. For example, counter logic 220 may snoop one or more of a command bus, an address bus, a data bus and/or one or more control lines coupled between a memory controller and memory device 200. Indication 222 may indicate to counter logic 220 a type of access to a row which has a potential to contribute to a row hammer condition for that row. By way of illustration and not limitation, indication 222 may correspond to an Activate command, a read command, a write command, an erase command and/or other command of commands 205 which, in combination with others of commands 205 to access an aggressor row, may pose a risk of data corruption in a physically adjacent victim row. In response to indication 222, counter logic 220 may increment a value stored in CP 214 which specifies a current access count for the accessed row. Such incrementing of an address count for a row may take place for each detected access of that row which is of a type that can contribute to a row hammer condition of that row.

Additionally or alternatively, counter logic 220 may detect, based on one or more of commands 205, an indication 224 of a reset event for a row in memory 210. For example, indication 224 may indicate to counter logic 220 a type of access to a row which at least temporarily reduces or eliminates some characteristic which might otherwise contribute to a row hammer condition for that row. By way of illustration and not limitation, indication 224 may be based on commands 205 including any of a variety of commands to implement, at least in part, a data refresh of a row, where DP 212 includes at least a portion of that row. In response to indication 224, counter logic 220 may set—e.g. reset—an access count in CP 214 to zero (0) or some other baseline value. Such resetting of an address count may indicate a baseline (e.g. lowest) level of risk of a row hammer condition for a row corresponding to that address count.

Memory device 200 may further include evaluation logic 230 to receive a current access count for a row of memory 210. For example, counter logic 220 may, in response to indication 222 or indication 224, provide to evaluation logic 230 an updated value of an access count for that row. In an embodiment, evaluation logic 230 compares the updated access count to a threshold value—e.g. to detect for a row hammer condition for that row. Based on such a comparison, evaluation logic 230 may directly generate a signal 235 indicating whether a row hammer condition has been detected. Signal 235 may, for example, be provided from memory device 200 to a memory controller.

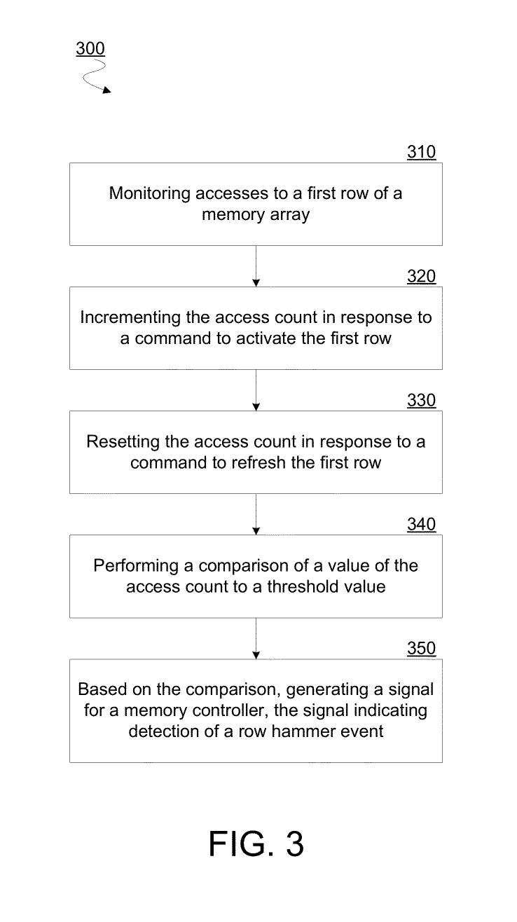

FIG. 3 illustrates elements of a method 300 for maintaining an access count for a row of memory according to an embodiment. Method 300 may be performed by a memory device operating in a system having some or all of the features of system 100, for example. In an embodiment, method 300 is performed by a memory device which provides functionality of memory device 200.

Method 300 may include, at 310, monitoring accesses to a first row of a memory array. The monitoring at 310 may, for example, include snooping one or more of a command bus, an address bus, a data bus and/or one or more control lines coupled between a memory controller and the memory device. Additionally or alternatively, the monitoring of accesses at 310 include determining whether (or not) an access increases, or decreases, a risk of a row hammer condition for the first row. By way of illustration and not limitation, determining that an access increases a risk of a row hammer condition may include determining that an access is for one of an Activate command to open a row, a read command to retrieve data from the first row and a write command to store data to the first row. Alternatively or in addition, determining that an access decreases a risk of a row hammer condition may include determining that an access is to implement, at least in part, a data refresh for that first row.

In an embodiment, method 300 includes one or more operations to maintain in the memory device an access count for the first row, where the maintaining is based on the monitoring at 310. The access count may, for example, specify or otherwise indicate a number of accesses—e.g. where such accesses are each of a particular type or types—which have taken place since a most recent reset event for the first row. The access count for a given row may be stored in the first row itself, although certain embodiments are not limited in this regard. Storing of an access count for a row may be automatic—e.g. where the storing is independent of any command from a memory controller explicitly requesting that the access count be stored. In an embodiment, the memory device includes dedicated count increment logic and/or dedicated count reset logic which is separate from conventional data read/write circuitry to access the first row. By way of illustration and not limitation, counter logic of the memory device may provide at least in part a separate write-back loop to retrieve an access count from a location—e.g. from a row to which the access count pertains—and to write an updated value of the access count back to the location. Such a write-back loop may be separate, for example, from all other signal lines of the memory device which are used to access data which is the subject of a read command or write command addressed to that row.

Maintaining the access count may include, at 320, incrementing the access count in response to a command to activate the first row. The incrementing at 320 may, for example, be in response to detecting an indication of an access (such as an access to read, write or erase data) which increases the risk of a row hammer condition. Additionally or alternatively, such maintaining of the access count may include, at 330, resetting the access count in response to a command to refresh the first row. Such resetting may, for example be in response to the monitoring at 310 detecting that an access—such as a command to implement a data refresh—decreases the risk of a row hammer condition.

Method 300 may further include, at 340, performing a comparison of a value of the access count to a threshold value—e.g. to detect whether a row hammer condition of the first row is indicated. The order of operations 320, 330 and 340 may vary with respect to one another, and may not be limiting in certain embodiments. For example, the incrementing at 320 and/or the comparison at 340 may be variously performed repeatedly before detection of a data refresh for the first row results in the resetting at 330. Based on the comparison at 340, method 300 may, at 350, generate a signal for a memory controller, the signal indicating detection of a row hammer event. The signal generated at 350 may, for example, include an ALERT signal compatible with the DDR4 specification, although certain embodiments are not limited in this regard.

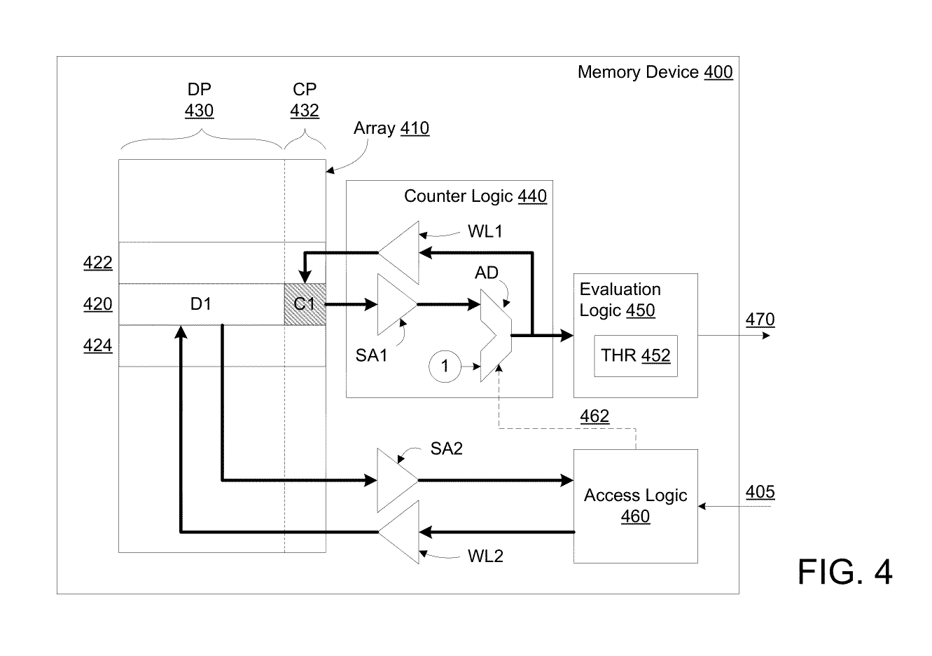

FIG. 4 illustrates elements of a memory device 400 to maintain an access count for a memory row according to an embodiment. Memory device 400 may include logic to implement method 300, for example. In an embodiment, memory device 400 includes some or all of the features of memory device 200.

Memory device 400 may include array 410 comprising storage cells to variously store data which, for example, is available for access by a memory controller (not shown) controlling memory device 400. Array 410 may include some or all of the features of memory array 140, for example. In an embodiment, array 410 comprises a plurality of addressable rows—e.g. including the illustrative rows 420, 422, 424. Array 410 may include a data portion DP 430 and a count portion CP 432 which, for example, provide respective functionality of DP 212 and CP 214. Rows 420, 422, 424 may each span both DP 212 and CP 214, although certain embodiment are not limited in this regard. By way of illustration and not limitation, row 420 may include a respective data portion D1 in DP 430—e.g. where a value stored in D1 is from the payload of a write command to access row 420. Additionally or alternatively, C1 may store a value specifying a current access count for row 420.

Memory device 400 may further include counter logic 440 coupled to array 410 (e.g. coupled to CP 432), where counter logic 440 includes hardware to maintain respective access counts for row 420 and, in an embodiment, for row 422 and/or row 424. For example, memory device 400 may receive, from a memory controller or other such agent, commands 405 including one or more commands to variously access row 420. Memory device 400 may include memory access logic 460 to receive commands 405 and to variously operate memory cells of array 410 for the purpose of servicing commands 405. Mechanisms of memory access logic 460 may be implemented according to any of a variety of conventional techniques which are not limiting on certain embodiments. In an embodiment, counter logic 440 detects, based on one or more of commands 405, an indication 462 of an access to row 420. For example, indication 462 may indicate to counter logic 440 a type of access to a row which has a potential to contribute to a row hammer condition for row 420. Such a row hammer condition may risk data corruption in one or more of rows 422, 424, which are each physically adjacent to row 420.

In response to indication 462, counter logic 440 may increment a value stored in C1—e.g. where such incrementing takes place for each detected access that can contribute to a row hammer condition of row 420. By way of illustration and not limitation, counter logic 440 may include sense amplifiers SA1 and an adder AD, where SA1 retrieves one or more bits of C1 and provides them as an operand for an add operation by AD. For example, AD may increment the value retrieved from C1—e.g. increment by 1—and provide the resulting output for storage in C1 as a new current access count for row 420. In an embodiment, the incremented access count is provided by write latch circuitry WL1 of counter logic 440.

Memory device 400 may further include evaluation logic 450 to receive a current access count for row 420—e.g. the incremented access count from AD—and compare that access count to a threshold value THR 452. The particular value of THR 452, which may depend on any of a variety of one or more implementation-specific factors, may not be limiting on certain embodiments. Based on a comparison of the current access count and THR 452, evaluation logic 450 may directly or indirectly send a signal 470 indicating a row hammer event. For example, evaluation logic 450 may cause signal 470 to be sent to a memory controller in response to detecting that a access count value is greater than (or in an embodiment, greater than or equal to) THR 452. Signal 470 may include an ALERT signal compatible with the DDR4 specification, although certain embodiments are not limited in this regard.

Alternatively, indication 462 may indicate to counter logic 440, based on one or more of commands 405, a reset event for row 420. For example, indication 462 indicate a type of access to row 420 which at least temporarily reduces or eliminates some characteristic which might otherwise contribute to a row hammer condition for row 420. By way of illustration and not limitation, indication 462 may be based on commands 405 including any of a variety of commands to implement, at least in part, a data refresh of row 420. In response to indication 462 indicating such a reset event, counter logic 440 may set—e.g. reset—C1 to store zero (0) or some other baseline value. For example, such resetting may include AD sending to WR1 one or more bits of the baseline value for storage in C1. In an embodiment, counter logic 440 provides, at least in part, a write-back loop to retrieve an access count value from C1 and to write an updated access count value back to C1, where the write-back loop is separate from sense amplifier circuitry, latch circuitry or other such logic to access D1 for servicing a read (or write) command. For example, SA1 may be separate from sense amplifiers SA2 to read data stored in D1 and/or WL1 may be separate from write latch circuitry WL2 for latching data to be written in D1.

In an embodiment, counter logic 440 and/or evaluation logic 450 are dedicated to maintaining an access count for row 420. For example, memory device 400 may further include other sets of circuitry (not shown) each dedicated to a respective one of rows 422, 424, the other sets of circuitry each to provide for the respective row functionality corresponding to that of counter logic 440 and/or evaluation logic 450. Additionally or alternatively, counter logic 440 and/or evaluation logic 450 may be shared for variously maintaining respective access counts for multiple rows of array 410.

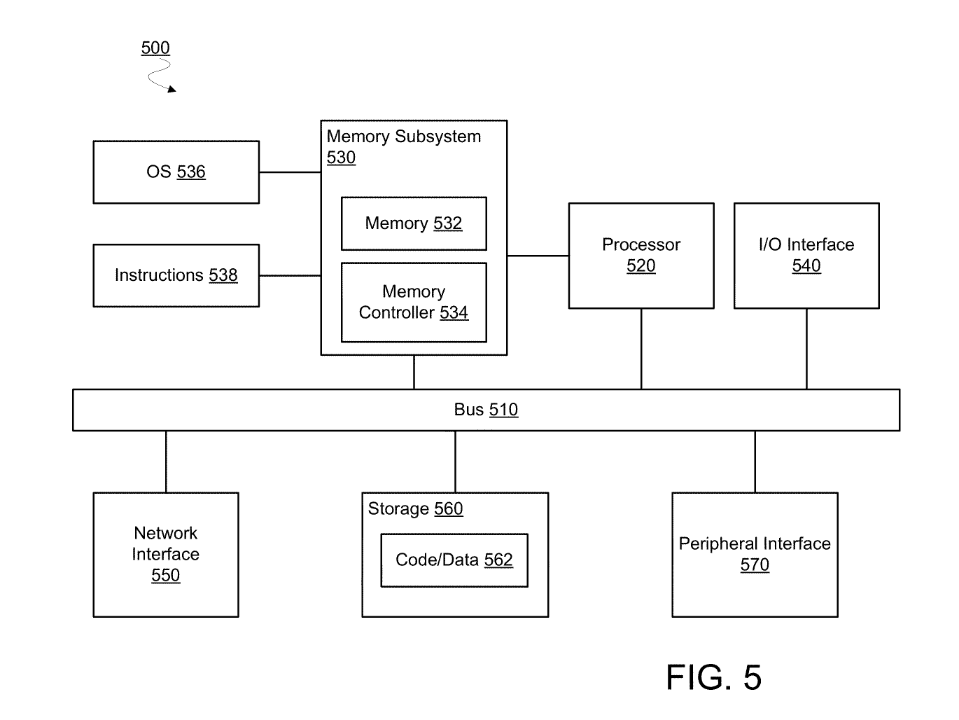

FIG. 5 is a block diagram of an embodiment of a computing system in which row hammer detection may be implemented. System 500 represents a computing device in accordance with any embodiment described herein, and may be a laptop computer, a desktop computer, a server, a gaming or entertainment control system, a scanner, copier, printer, or other electronic device. System 500 may include processor 520, which provides processing, operation management, and execution of instructions for system 500. Processor 520 may include any type of microprocessor, central processing unit (CPU), processing core, or other processing hardware to provide processing for system 500. Processor 520 controls the overall operation of system 500, and may be or include, one or more programmable general-purpose or special-purpose microprocessors, digital signal processors (DSPs), programmable controllers, application specific integrated circuits (ASICs), programmable logic devices (PLDs), or the like, or a combination of such devices.

Memory subsystem 530 represents the main memory of system 500, and provides temporary storage for code to be executed by processor 520, or data values to be used in executing a routine. Memory subsystem 530 may include one or more memory devices such as read-only memory (ROM), flash memory, one or more varieties of random access memory (RAM), or other memory devices, or a combination of such devices. Memory subsystem 530 stores and hosts, among other things, operating system (OS) 536 to provide a software platform for execution of instructions in system 500. Additionally, other instructions 538 are stored and executed from memory subsystem 530 to provide the logic and the processing of system 500. OS 536 and instructions 538 are executed by processor 520.

Memory subsystem 530 may include memory device 532 where it stores data, instructions, programs, or other items. In one embodiment, memory subsystem includes memory controller 534, which is a memory controller in accordance with any embodiment described herein, and which provides row hammer detection mechanisms. In one embodiment, memory controller 534 provides commands to memory device 532 each based on a detected row hammer condition. The commands may be for memory device 532 to perform targeted refreshes for respective potential victim rows.

Processor 520 and memory subsystem 530 are coupled to bus/bus system 510. Bus 510 is an abstraction that represents any one or more separate physical buses, communication lines/interfaces, and/or point-to-point connections, connected by appropriate bridges, adapters, and/or controllers. Therefore, bus 510 may include, for example, one or more of a system bus, a Peripheral Component Interconnect (PCI) bus, a HyperTransport or industry standard architecture (ISA) bus, a small computer system interface (SCSI) bus, a universal serial bus (USB), or an Institute of Electrical and Electronics Engineers (IEEE) standard 1394 bus (commonly referred to as “Firewire”). The buses of bus 510 may also correspond to interfaces in network interface 550.

System 500 may also include one or more input/output (I/O) interface(s) 540, network interface 550, one or more internal mass storage device(s) 560, and peripheral interface 570 coupled to bus 510. I/O interface 540 may include one or more interface components through which a user interacts with system 500 (e.g., video, audio, and/or alphanumeric interfacing). Network interface 550 provides system 500 the ability to communicate with remote devices (e.g., servers, other computing devices) over one or more networks. Network interface 550 may include an Ethernet adapter, wireless interconnection components, USB (universal serial bus), or other wired or wireless standards-based or proprietary interfaces.

Storage 560 may be or include any conventional medium for storing large amounts of data in a nonvolatile manner, such as one or more magnetic, solid state, or optical based disks, or a combination. Storage 560 holds code or instructions and data 562 in a persistent state (i.e., the value is retained despite interruption of power to system 500). Storage 560 may be generically considered to be a “memory,” although memory 530 is the executing or operating memory to provide instructions to processor 520. Whereas storage 560 is nonvolatile, memory 530 may include volatile memory (i.e., the value or state of the data is indeterminate if power is interrupted to system 500).

Peripheral interface 570 may include any hardware interface not specifically mentioned above. Peripherals refer generally to devices that connect dependently to system 500. A dependent connection is one where system 500 provides the software and/or hardware platform on which operation executes, and with which a user interacts.

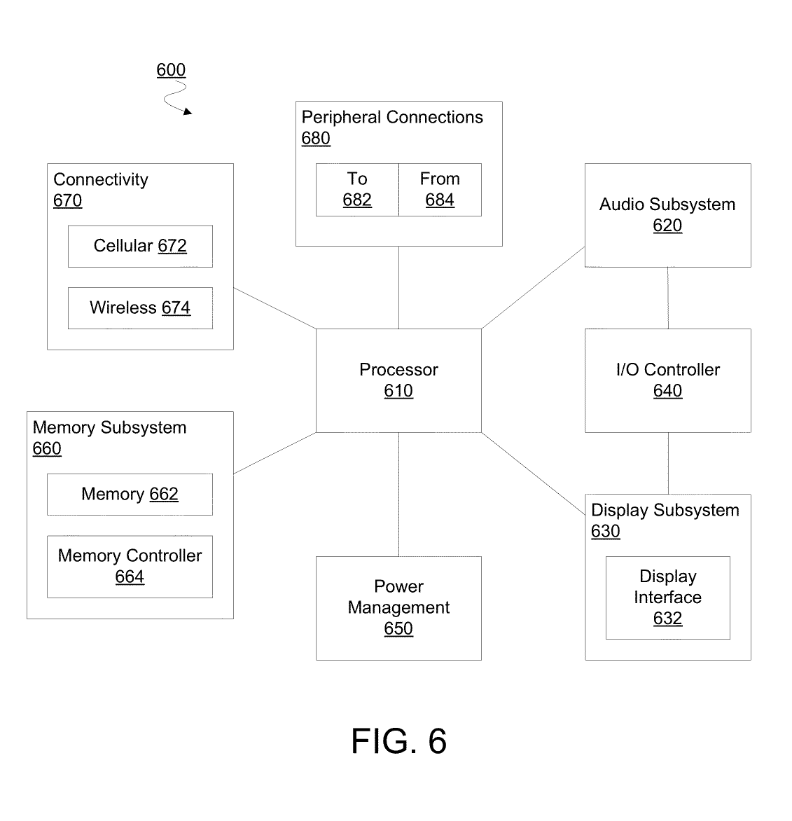

FIG. 6 is a block diagram of an embodiment of a mobile device in which row hammer detection may be implemented. Device 600 represents a mobile computing device, such as a computing tablet, a mobile phone or smartphone, a wireless-enabled e-reader, or other mobile device. It will be understood that certain of the components are shown generally, and not all components of such a device are shown in device 600.

Device 600 may include processor 610, which performs the primary processing operations of device 600. Processor 610 may include one or more physical devices, such as microprocessors, application processors, microcontrollers, programmable logic devices, or other processing means. In one embodiment, processor 610 includes optical interface components in addition to a processor die. Thus, the processor die and photonic components are in the same package. Such a processor package may interface optically with an optical connector in accordance with any embodiment described herein.

The processing operations performed by processor 610 include the execution of an operating platform or operating system on which applications and/or device functions are executed. The processing operations include operations related to I/O (input/output) with a human user or with other devices, operations related to power management, and/or operations related to connecting device 600 to another device. The processing operations may also include operations related to audio I/O and/or display I/O.

In one embodiment, device 600 includes audio subsystem 620, which represents hardware (e.g., audio hardware and audio circuits) and software (e.g., drivers, codecs) components associated with providing audio functions to the computing device. Audio functions may include speaker and/or headphone output, as well as microphone input. Devices for such functions may be integrated into device 600, or connected to device 600. In one embodiment, a user interacts with device 600 by providing audio commands that are received and processed by processor 610.

Display subsystem 630 represents hardware (e.g., display devices) and software (e.g., drivers) components that provide a visual and/or tactile display for a user to interact with the computing device. Display subsystem 630 may include display interface 632, which may include the particular screen or hardware device used to provide a display to a user. In one embodiment, display interface 632 includes logic separate from processor 610 to perform at least some processing related to the display. In one embodiment, display subsystem 630 includes a touchscreen device that provides both output and input to a user.

I/O controller 640 represents hardware devices and software components related to interaction with a user. I/O controller 640 may operate to manage hardware that is part of audio subsystem 620 and/or display subsystem 630. Additionally, I/O controller 640 illustrates a connection point for additional devices that connect to device 600 through which a user might interact with the system. For example, devices that may be attached to device 600 might include microphone devices, speaker or stereo systems, video systems or other display device, keyboard or keypad devices, or other I/O devices for use with specific applications such as card readers or other devices.

As mentioned above, I/O controller 640 may interact with audio subsystem 620 and/or display subsystem 630. For example, input through a microphone or other audio device may provide input or commands for one or more applications or functions of device 600. Additionally, audio output may be provided instead of or in addition to display output. In another example, if display subsystem includes a touchscreen, the display device also acts as an input device, which may be at least partially managed by I/O controller 640. There may also be additional buttons or switches on device 600 to provide I/O functions managed by I/O controller 640.

In one embodiment, I/O controller 640 manages devices such as accelerometers, cameras, light sensors or other environmental sensors, gyroscopes, global positioning system (GPS), or other hardware that may be included in device 600. The input may be part of direct user interaction, as well as providing environmental input to the system to influence its operations (such as filtering for noise, adjusting displays for brightness detection, applying a flash for a camera, or other features).

In one embodiment, device 600 includes power management 650 that manages battery power usage, charging of the battery, and features related to power saving operation. Memory subsystem 660 may include memory device(s) 662 for storing information in device 600. Memory subsystem 660 may include nonvolatile (state does not change if power to the memory device is interrupted) and/or volatile (state is indeterminate if power to the memory device is interrupted) memory devices. Memory 660 may store application data, user data, music, photos, documents, or other data, as well as system data (whether long-term or temporary) related to the execution of the applications and functions of system 600.

In one embodiment, memory subsystem 660 includes memory controller 664 (which could also be considered part of the control of system 600, and could potentially be considered part of processor 610). Memory controller 664 monitors for a row hammer condition. For example, memory controller 664 may monitor the requests to certain memory addresses, and log how many times a specific address is the subject of a request. In an embodiment, memory controller 664 issues commands for targeted refreshes of potential victim rows of memory 662—e.g. in the absence of memory controller 664 determining an address offset for physically adjacent rows of memory 662.

Connectivity 670 may include hardware devices (e.g., wireless and/or wired connectors and communication hardware) and software components (e.g., drivers, protocol stacks) to enable device 600 to communicate with external devices. The device could be separate devices, such as other computing devices, wireless access points or base stations, as well as peripherals such as headsets, printers, or other devices.

Connectivity 670 may include multiple different types of connectivity. To generalize, device 600 is illustrated with cellular connectivity 672 and wireless connectivity 674. Cellular connectivity 672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4 G”), or other cellular service standards. Wireless connectivity 674 refers to wireless connectivity that is not cellular, and may include personal area networks (such as Bluetooth), local area networks (such as WiFi), and/or wide area networks (such as WiMax), or other wireless communication. Wireless communication refers to transfer of data through the use of modulated electromagnetic radiation through a non-solid medium. Wired communication occurs through a solid communication medium.

Peripheral connections 680 include hardware interfaces and connectors, as well as software components (e.g., drivers, protocol stacks) to make peripheral connections. It will be understood that device 600 could both be a peripheral device (“to” 682) to other computing devices, as well as have peripheral devices (“from” 684) connected to it. Device 600 commonly has a “docking” connector to connect to other computing devices for purposes such as managing (e.g., downloading and/or uploading, changing, synchronizing) content on device 600. Additionally, a docking connector may allow device 600 to connect to certain peripherals that allow device 600 to control content output, for example, to audiovisual or other systems.

In addition to a proprietary docking connector or other proprietary connection hardware, device 600 may make peripheral connections 680 via common or standards-based connectors. Common types may include a Universal Serial Bus (USB) connector (which may include any of a number of different hardware interfaces), DisplayPort including MiniDisplayPort (MDP), High Definition Multimedia Interface (HDMI), Firewire, or other type.

In one aspect, a memory device comprises an array including a first row, and counter logic coupled to the array, the counter logic to monitor accesses to the first row. Based on the monitored accesses, the counter logic is to maintain in the memory device an access count for the first row, including the counter logic to increment the access count in response to a command to activate the first row, and the counter logic to reset the access count in response to a command to refresh the first row. The memory device further comprises evaluation logic to perform a comparison of a value of the access count to a threshold value and, based on the comparison, to generate a signal for a memory controller, the signal to indicate detection of a row hammer event.

In an embodiment, the counter logic to monitor includes the counter logic to snoop one or more of a command bus, an address bus, a data bus and a more control line coupled between the memory device and a memory controller. In an embodiment, the counter logic to monitor includes the counter logic to determine that an access increases a risk of a row hammer condition. In an embodiment, the counter logic to determine that the access increases the risk includes the counter logic to determine that the access is for an Activate command, a read command or a write command.

In an embodiment, the counter logic to monitor includes the counter logic to determine that an access decreases a risk of a row hammer condition. In an embodiment, the counter logic to determine that the access decreases the risk includes the counter logic to determine that the access is for a data refresh of the first row. In an embodiment, the memory device includes dynamic random access memory. In an embodiment, the access count is stored in the first row.

In another aspect, a memory subsystem comprises a memory controller and a memory device coupled to the memory, the memory device comprising an array including a first row, and counter logic coupled to the array, the counter logic to monitor accesses to the first row. Based on the monitored accesses, the counter logic is to maintain in the memory device an access count for the first row, including the counter logic to increment the access count in response to a command to activate the first row, and the counter logic to reset the access count in response to a command to refresh the first row. The memory device further comprises evaluation logic to perform a comparison of a value of the access count to a threshold value and, based on the comparison, to generate a signal for the memory controller, the signal to indicate detection of a row hammer event.

In an embodiment, the counter logic to monitor includes the counter logic to snoop one or more of a command bus, an address bus, a data bus and a more control line coupled between the memory device and the memory controller. In an embodiment, the counter logic to monitor includes the counter logic to determine that an access increases a risk of a row hammer condition. In an embodiment, the counter logic to determine that the access increases the risk includes the counter logic to determine that the access is for an Activate command, a read command or a write command.

In an embodiment, the counter logic to monitor includes the counter logic to determine that an access decreases a risk of a row hammer condition. In an embodiment, the counter logic to determine that the access decreases the risk includes the counter logic to determine that the access is for a data refresh of the first row. In an embodiment, the memory device includes dynamic random access memory. In an embodiment, the access count is stored in the first row.

In another aspect, a method at a memory device comprises monitoring accesses to a first row of a memory array and, based on the monitoring, maintaining in the memory device an access count for the first row, including incrementing the access count in response to a command to activate the first row, and resetting the access count in response to a command to refresh the first row. The method further comprises performing a comparison of a value of the access count to a threshold value, and based on the comparison, generating a signal for a memory controller, the signal indicating detection of a row hammer event.

In an embodiment, the monitoring includes determining that an access increases a risk of a row hammer condition. In an embodiment, determining that the access increases the risk includes determining that the access is for an Activate command, a read command or a write command. In an embodiment, the monitoring includes determining that an access decreases a risk of a row hammer condition. In an embodiment, determining that the access decreases the risk includes determining that the access is for a data refresh of the first row. In an embodiment, the memory device includes dynamic random access memory. In an embodiment, the access count is stored in the first row.

In another aspect, a computer-readable storage medium has stored thereon instructions which, when executed by one or more processing units, cause the one or more processing units to perform a method. The method comprises monitoring accesses to a first row of a memory array and, based on the monitoring, maintaining in the memory device an access count for the first row, including incrementing the access count in response to a command to activate the first row, and resetting the access count in response to a command to refresh the first row. The method further comprises performing a comparison of a value of the access count to a threshold value, and based on the comparison, generating a signal for a memory controller, the signal indicating detection of a row hammer event.

In an embodiment, the monitoring includes determining that an access increases a risk of a row hammer condition. In an embodiment, determining that the access increases the risk includes determining that the access is for an Activate command, a read command or a write command. In an embodiment, the monitoring includes determining that an access decreases a risk of a row hammer condition. In an embodiment, determining that the access decreases the risk includes determining that the access is for a data refresh of the first row. In an embodiment, the memory device includes dynamic random access memory. In an embodiment, the access count is stored in the first row.

Techniques and architectures for operating a memory device are described herein. In the above description, for purposes of explanation, numerous specific details are set forth in order to provide a thorough understanding of certain embodiments. It will be apparent, however, to one skilled in the art that certain embodiments can be practiced without these specific details. In other instances, structures and devices are shown in block diagram form in order to avoid obscuring the description.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

Some portions of the detailed description herein are presented in terms of algorithms and symbolic representations of operations on data bits within a computer memory. These algorithmic descriptions and representations are the means used by those skilled in the computing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the discussion herein, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Certain embodiments also relate to apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, any type of disk including floppy disks, optical disks, CD-ROMs, and magnetic-optical disks, read-only memories (ROMs), random access memories (RAMs) such as dynamic RAM (DRAM), EPROMs, EEPROMs, magnetic or optical cards, or any type of media suitable for storing electronic instructions, and coupled to a computer system bus.

The algorithms and displays presented herein are not inherently related to any particular computer or other apparatus. Various general purpose systems may be used with programs in accordance with the teachings herein, or it may prove convenient to construct more specialized apparatus to perform the required method steps. The required structure for a variety of these systems will appear from the description herein. In addition, certain embodiments are not described with reference to any particular programming language. It will be appreciated that a variety of programming languages may be used to implement the teachings of such embodiments as described herein.

Besides what is described herein, various modifications may be made to the disclosed embodiments and implementations thereof without departing from their scope. Therefore, the illustrations and examples herein should be construed in an illustrative, and not a restrictive sense. The scope of the invention should be measured solely by reference to the claims that follow.

What is claimed is:

1. A memory device comprising:
an array including a first row;
counter logic coupled to the array, the counter logic to monitor accesses to the first row and, based on the monitored accesses, to maintain in the memory device an access count for the first row, including:
the counter logic to increment the access count in response to a command to activate the first row, and
the counter logic to reset the access count in response to a command to refresh the first row; and
evaluation logic to perform a comparison of a value of the access count to a threshold value and, based on the comparison, to generate a signal for a memory controller, the signal to indicate detection of a row hammer event.

2. The memory device of claim 1, wherein the counter logic to monitor includes the counter logic to snoop one or more of a command bus, an address bus, a data bus and a more control line coupled between the memory device and a memory controller.

3. The memory device of claim 1, wherein the counter logic to monitor includes the counter logic to determine that an access increases a risk of a row hammer condition.

4. The memory device of claim 3, wherein the counter logic to determine that the access increases the risk includes the counter logic to determine that the access is for an Activate command, a read command or a write command.

5. The memory device of claim 1, wherein the counter logic to monitor includes the counter logic to determine that an access decreases a risk of a row hammer condition.

6. The memory device of claim 5, wherein the counter logic to determine that the access decreases the risk includes the counter logic to determine that the access is for a data refresh of the first row.

7. The memory device of claim 1, wherein the memory device includes dynamic random access memory.

8. The memory device of claim 1, wherein the access count is stored in the first row.

9. A memory subsystem comprising:
a memory controller; and
a memory device coupled to the memory, the memory device comprising:
an array including a first row;
counter logic coupled to the array, the counter logic to monitor accesses to the first row and, based on the monitored accesses, to maintain in the memory device an access count for the first row, including:
the counter logic to increment the access count in response to a command to activate the first row, and
the counter logic to reset the access count in response to a command to refresh the first row; and
evaluation logic to perform a comparison of a value of the access count to a threshold value and, based on the comparison, to generate a signal for the memory controller, the signal to indicate detection of a row hammer event.

10. The memory subsystem of claim 9, wherein the counter logic to monitor includes the counter logic to snoop one or more of a command bus, an address bus, a data bus and a more control line coupled between the memory device and the memory controller.

11. The memory subsystem of claim 9, wherein the counter logic to monitor includes the counter logic to determine that an access increases a risk of a row hammer condition.

12. The memory subsystem of claim 11, wherein the counter logic to determine that the access increases the risk includes the counter logic to determine that the access is for an Activate command, a read command or a write command.

13. The memory subsystem of claim 9, wherein the counter logic to monitor includes the counter logic to determine that an access decreases a risk of a row hammer condition.

14. The memory subsystem of claim 13, wherein the counter logic to determine that the access decreases the risk includes the counter logic to determine that the access is for a data refresh of the first row.

15. The memory subsystem of claim 9, wherein the memory device includes dynamic random access memory.

16. The memory subsystem of claim 9, wherein the access count is stored in the first row.

17. A method at a memory device, the method comprising:
monitoring accesses to a first row of a memory array;
based on the monitoring, maintaining in the memory device an access count for the first row, including:
incrementing the access count in response to a command to activate the first row; and
resetting the access count in response to a command to refresh the first row;
performing a comparison of a value of the access count to a threshold value; and
based on the comparison, generating a signal for a memory controller, the signal indicating detection of a row hammer event.

18. The method of claim 17, wherein the monitoring includes determining that an access increases a risk of a row hammer condition.

19. The method of claim 18, wherein determining that the access increases the risk includes determining that the access is for an Activate command, a read command or a write command.

20. The method of claim 17, wherein the monitoring includes determining that an access decreases a risk of a row hammer condition.

21. The method of claim 20, wherein determining that the access decreases the risk includes determining that the access is for a data refresh of the first row.

22. The method of claim 17, wherein the memory device includes dynamic random access memory.

23. The method of claim 17, wherein the access count is stored in the first row.

24. A computer-readable storage medium having stored thereon instructions which, when executed by one or more processing units, cause the one or more processing units to perform a method comprising:
monitoring accesses to a first row of a memory array;
based on the monitoring, maintaining in the memory device an access count for the first row, including:
incrementing the access count in response to a command to activate the first row; and
resetting the access count in response to a command to refresh the first row;
performing a comparison of a value of the access count to a threshold value; and
based on the comparison, generating a signal for a memory controller, the signal indicating detection of a row hammer event.

25. The computer-readable storage medium of claim 24, wherein the monitoring includes determining that an access increases a risk of a row hammer condition.

26. The computer-readable storage medium of claim 25, wherein determining that the access increases the risk includes determining that the access is for an Activate command, a read command or a write command.

27. The computer-readable storage medium of claim 24, wherein the monitoring includes determining that an access decreases a risk of a row hammer condition.

28. The computer-readable storage medium of claim 27, wherein determining that the access decreases the risk includes determining that the access is for a data refresh of the first row.

29. The computer-readable storage medium of claim 24, wherein the memory device includes dynamic random access memory.

30. The computer-readable storage medium of claim 24, wherein the access count is stored in the first row.
